(19) United States
(12) Patent Application Publication
(10) Pub. No.: US 2014/0210011 A1
(43) Pub. Date: Jul. 31, 2014

(54) Dual Silicide Process

(71) Applicant: INTERNATIONAL BUSINESS MACHINES CORPORATION, Armonk, NY (US)

(72) Inventors: Ashish K. Baraskar, White Plains, NY (US); Cyril Cabral, Mahopac, NY (US); Siyuranga O. Koswatta, Bedford Hills, NY (US); Christian Lavoie, Ossining, NY (US); Ahmet S. Ozcan, Pleasantville, NY (US); Li Yang, Santa Clara, CA (US); Zhen Zhang, Ossining, NY (US)

(73) Assignees: GLOBALFOUNDRIES Inc, Ugland House (KY); International Business Machines Corporation, Armonk, NY (US)

(21) Appl. No.: 13/755,427

(22) Filed: Jan. 31, 2013

(51) Int. Cl. H01L 21/8238; H01L 27/092

(52) U.S. Cl. CPC H01L 21/823814; H01L 27/092
USPC 257/369; 438/233

(57) ABSTRACT

In one aspect, a method for silicidation includes the steps of: (a) providing a wafer having at least one first active area and at least one second active area defined therein; (b) masking the first active area with a first hardmask; (c) doping the second active area; (d) forming a silicide in the second active area, wherein the first hardmask serves to mask the first active area during both the doping step (c) and the forming step (d); (e) removing the first hardmask; (f) masking the second active area with a second hardmask; (g) doping the first active area; (h) forming a silicide in the first active area, wherein the second hardmask serves to mask the second active area during both the doping step (g) and the forming step (h); and (i) removing the second hardmask.

### FIELD OF THE INVENTION

The present invention relates to silicide formation and more particularly, to improved techniques for implementing a dual silicide in an electronic device process flow and techniques to enable implementation of the present process in a replacement gate flow if so desired.

### BACKGROUND OF THE INVENTION

Silicide/silicon contact resistance becomes increasingly more problematic in an extremely scaled device. A dual silicide process can drop contact resistance on both (n- and p-) types of contacts by using one metal on p-contacts and another metal on n-contacts with matched work functions.

However, using conventional techniques a dual silicide process is difficult to implement in practice. Namely, the dual silicide process would require additional mask levels for the silicidation step. Thus, a dual silicide process in conventional process flows would increase production complexity and manufacturing costs.

Accordingly, improved dual silicide processes that minimize production complexity and costs would be desirable.

### SUMMARY OF THE INVENTION

The present invention provides improved techniques for implementing a dual silicide in an electronic device process flow. In one aspect of the invention, a method for silicidation is provided. The method includes the steps of: (a) providing a wafer having at least one first active area and at least one second active area defined therein; (b) masking the first active area with a first hardmask; (c) doping the second active area; (d) forming a silicide in the second active area including at least one metal having a melting point that is greater than about 1,200° C., wherein the first hardmask serves to mask the first active area during both the doping step (c) and the forming step (d); (e) removing the first hardmask; (f) masking the second active area with a second hardmask; (g) doping the first active area; (h) forming a silicide in the first active area including at least one metal having a melting point that is greater than about 1,200° C., wherein the second hardmask serves to mask the second active area during both the doping step (g) and the forming step (h); and (i) removing the second hardmask.

In another aspect of the invention, an electronic device is provided. The electronic device includes a wafer having at least one first active area and at least one second active area defined therein; at least one p-FET device formed in the first active area of the wafer, the p-FET device having doped p-FET source and drain regions, and silicide contacts to the p-FET source and drain regions, wherein the silicide contacts to the p-FET source and drain regions include at least one metal having a melting point that is greater than about 1,200° C.; and at least one n-FET device formed in the second active area of the wafer, the n-FET device having doped n-FET source and drain regions and silicide contacts to the n-FET source and drain regions, wherein the silicide contacts to the n-FET source and drain regions include at least one metal having a melting point that is greater than about 1,200° C.

A more complete understanding of the present invention, as well as further features and advantages of the present invention, will be obtained by reference to the following detailed description and drawings.

### BRIEF DESCRIPTION OF THE DRAWINGS

FIG. 1 is a cross-sectional diagram illustrating a starting platform for a dual silicidation process that includes a wafer in which one or more active areas (corresponding to p-FET and n-FET devices) have been defined and a gate stack having been formed over each of the active areas according to an embodiment of the present invention;

FIG. 2 is a cross-sectional diagram illustrating a hardmask having been formed covering/masking the p-FET device(s) and doped source and drain regions having been formed in the n-FET devices according to an embodiment of the present invention;

FIG. 3 is a cross-sectional diagram illustrating an optional surface treatment of the n-FET device source and drain regions having been performed according to an embodiment of the present invention;

FIG. 4 is a cross-sectional diagram illustrating an anneal having been performed to intersperse a (refractory) metal(s) within the source and drain regions of the n-FET devices to form a silicide according to an embodiment of the present invention;

FIG. 5 is a cross-sectional diagram illustrating a hardmask having been formed covering/masking the n-FET device(s) and doped source and drain regions having been formed in the p-FET devices according to an embodiment of the present invention;

FIG. 6 is a cross-sectional diagram illustrating an optional surface treatment of the p-FET device source and drain regions having been performed according to an embodiment of the present invention;

FIG. 7 is a cross-sectional diagram illustrating an anneal having been performed to intersperse a (refractory) metal(s) within the source and drain regions of the p-FET devices to form a silicide according to an embodiment of the present invention;

FIG. 8 is a cross-sectional diagram illustrating the hardmask having been removed from the n-FET devices according to an embodiment of the present invention;

FIG. 9A is a cross-sectional diagram illustrating for an optional gate last process a filler layer having been deposited onto the wafer and planarized according to an embodiment of the present invention;

FIG. 9B is a cross-sectional diagram illustrating the dummy gates having been removed selective to the filler layer forming trenches in the filler layer according to an embodiment of the present invention; and

FIG. 9C is a cross-sectional diagram illustrating the trenches in the filler layer having been filled with a replacement gate material(s) to form replacements gates according to an embodiment of the present invention.

### DETAILED DESCRIPTION OF PREFERRED EMBODIMENTS

As provided above, a dual silicide process can advantageously be used to address contact resistance issues, however with conventional processes the implementation of a dual silicide process increases production complexity (e.g., by requiring multiple masking levels) and thus invariably increases manufacturing costs. Provided herein are techniques which avoid these problems by way of a novel process flow which employs the source/drain doping and epitaxy mask as the masks for the dual silicide. This use of a single doping/epitaxy and silicide mask greatly reduces the production complexity. As will be described in detail below, in order to be able to implement the present single doping/epitaxy and silicide mask scheme it is preferred that refractory metals are used as the contact materials. Refractory metals are able to withstand higher processing temperatures, which according to the present techniques enable their use during the doping anneals.

Further, advantageously, by using refractory metals as the contact materials the present techniques can be implemented in a self-aligned silicide process (silicide first) for the gate last fabrication scheme, which can maximize the contact area for a fixed gate pitch. Specifically, a silicide first, gate last approach involves forming a dummy gate, performing the silicidation and then replacing the dummy gate with a replacement gate. Forming the replacement gate generally involves a high temperature anneal (e.g., to set the workfunction of the gate). Conventional silicide metals would be degraded during this anneal. By contrast, the present refractory metals do not have the same temperature constraints. It is notable however that, as will be described in detail below, the use of a dummy gate/replacement gate scheme is merely one example, and that the present techniques are more generally applicable to any dual silicide process.

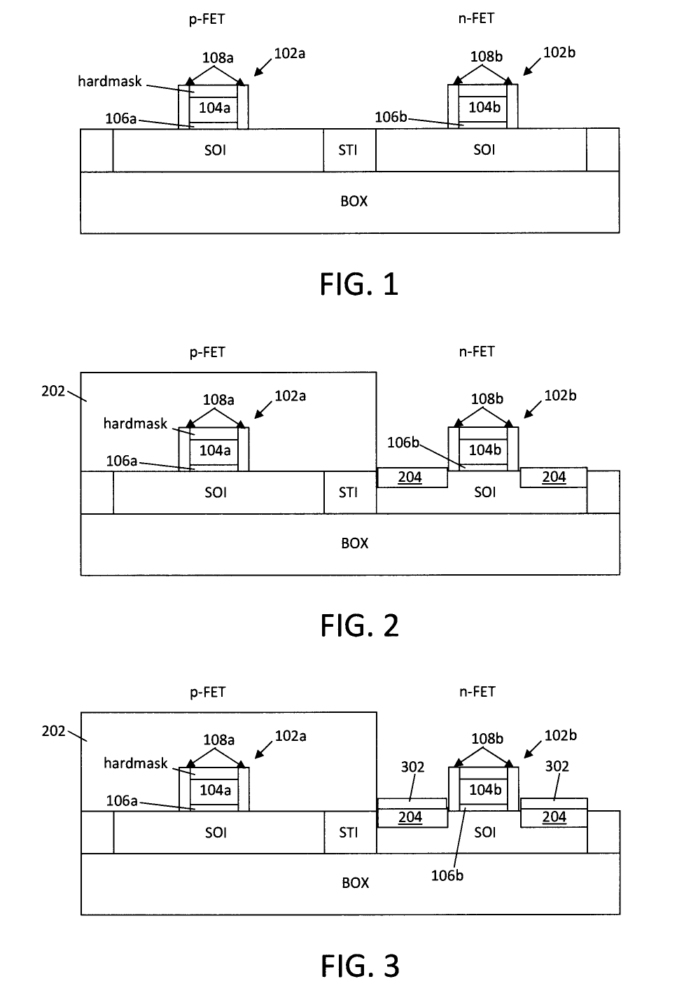

The present techniques will now be described in detail by way of reference to FIGS. 1-9 which depict an exemplary dual silicide device fabrication process flow. As shown in FIG. 1, the starting platform for the process is a wafer in which one or more active areas have been defined. For illustrative purposes, the figures provided herein depict the formation of two devices, one p-channel field effect transistor (p-FET) and one n-channel FET (n-FET). Of course the number and/or types of devices formed can vary in accordance with the present teachings, and the configurations shown were chosen merely to illustrate the present dual silicide process. Further, in the following description reference may be made to structures in multiple, e.g., multiple active areas, gate stacks, hardmasks, etc. In such cases, for ease and clarity of description, these structures may also be referred to using the qualifiers first, second, etc., e.g., first active area, second active area, etc.

By way of example only, the starting wafer can be a semiconductor-on-insulator (SOI) wafer or a bulk semiconductor wafer. A SOI wafer includes a SOI layer (e.g., silicon (Si), germanium (Ge), silicon-germanium (SiGe), etc. separated from a substrate by a buried oxide or BOX. See FIG. 1. For ease of depiction, the underlying substrate is not shown in the figures. With an SOI wafer, the active areas can be defined using a shallow trench isolation (STI) process, where trenches are patterned in the wafer and then filled with an insulator to form STI regions. In the SOI wafer example, the STI regions extend through the SOI layer (see, for example, FIG. 1).

Suitable bulk semiconductor wafers include, but are not limited to, bulk Si, Ge, or SiGe wafers. STI can also be used to define active areas in a bulk wafer.

As shown in FIG. 1, a gate stack 102a, 102b, etc. has been formed over each of the active areas of the wafer. Each gate stack includes a gate electrode 104a, 104b, etc. over a gate dielectric 106a, 106b, etc. By way of example only, the gate electrode may be formed from a metal(s) and/or doped polysilicon. The gate dielectric may be formed from an oxide, such as silicon oxide, or hafnium oxide. High-k dielectrics, such as hafnium oxide, are preferable when a metal gate electrode is employed. It is notable that the configuration of the gate electrode depicted in the figures is merely exemplary. By way of example only, gate stack configurations without a gate dielectric are possible.

The gate stacks may be formed by forming/depositing the gate stack materials (e.g., the gate dielectric, the gate electrode material, etc.) on the wafer and then patterning the materials into the individual gate stacks. A hardmask is used during the patterning. See, for example, FIG. 1. This gate stack hardmask may be left in place to protect the gate stacks during subsequent processing steps. As shown in FIG. 1, spacers 108a, 108b, etc. are present, formed on opposite sides of each of the gate stacks. The spacers may be formed by depositing a suitable spacer material, such as silicon nitride, onto the wafer and then patterning the spacer material into the individual spacers shown.

In general, each FET device includes a source region and a drain region interconnected by a channel. The gate stack is located over the channel and regulates electron flow through the channel.

As described above, due to the use of high-temperature resistant refractory contact metals, the present dual silicide process may uniquely be implemented in a gate-last fabrication process flow. In a gate-last process, a dummy gate is formed early on in the process which acts as a placeholder for a replacement gate that, once the dummy gate is removed, will replace the dummy gate. In the case where the present techniques are being implemented in accordance with a gate-last process flow, the gate stacks shown in FIG. 1 represent the dummy gates. Dummy gates are commonly formed from poly-silicon—and may be patterned in the same manner as described above. A dummy gate dielectric may be employed to permit selective removal of the dummy gates relative to the underlying channel material. In this exemplary gate-last scenario, the gate electrodes 104a, 104b, etc. would be poly-silicon and the gate dielectrics 106a, 106b, etc. would be an oxide, such as silicon dioxide.

Next, one of the device types (n-FET or p-FET) is masked off while doping/epitaxy followed by silicidation of the source and drain regions of the other device type is performed. Thus, as will become apparent from the following description, a single mask will be used for the doping/epitaxy and silicidation of each device type. It is notable that in the following exemplary process flow the p-FET devices are masked first and the n-FET source/drain doping and silicidation are performed, followed by masking of the n-FET devices and doping and silicidation of the p-FET source/drain regions. This is however merely exemplary. For instance, the process could, in the same manner described, begin with doping and silicidation of the p-FET devices first.

As shown in FIG. 2, a hardmask 202 is formed covering/masking the p-FET device(s). By way of example only, the hardmask 202 can be formed from silicon oxide or silicon nitride. In the case where the present dual silicide process is being performed for multiple p-FET and n-FET devices on a common wafer, all of the p-FET devices on the wafer will at this stage be masked off relative to all of the n-FET devices. The hardmask 202 may be formed by blanket depositing a suitable hardmask material (e.g., silicon nitride) onto the wafer, covering the gate stacks, and then using conventional lithography and etching processes to pattern the hardmask 202.

Next, source and drain regions 204 are formed in the n-FET devices. Doping of the source and drain regions may be performed in-situ or ex-situ. For example, the dopants may be introduced during growth of an epitaxial material (e.g., epitaxial Si, Ge, SiGe, etc.) in the source drain regions of the n-FET devices, resulting in in-situ doped epitaxial source/drain regions. An activation anneal may then be performed to activate the dopants. Alternatively, ex-situ doping might involve implanting a dopant or dopants and then activating the dopants by way of an activation anneal. Phosphorous (P), arsenic (As), and antimony (Sb) are suitable n-type dopants and boron (B), aluminum (Al), indium (In), and gallium (Ga) are suitable p-type dopants. Dopant concentrations of from about 1×10¹⁹ atoms per cubic centimeter (atoms/cm³) to about 1×10²² atoms/cm³ may be employed. The activation anneal of the wafer may be performed at a temperature of from about 800° C. to about 1,500° C.

As shown in FIG. 3, an optional surface treatment 302 of the n-FET device source and drain regions may be performed, if so desired, using shallow surface implantation or atomic layer deposition (ALD) of dopants. Such a surface treatment can be used to reduce the metal/semiconductor interface resistance. According to an exemplary embodiment, the dopant(s) are applied at a concentration of from about 1×10¹⁹/cm³ to pure atomic layers of dopants. As provided above, P, As, and Sb are suitable n-type dopants and B, Al, In, and Ga are suitable p-type dopants.

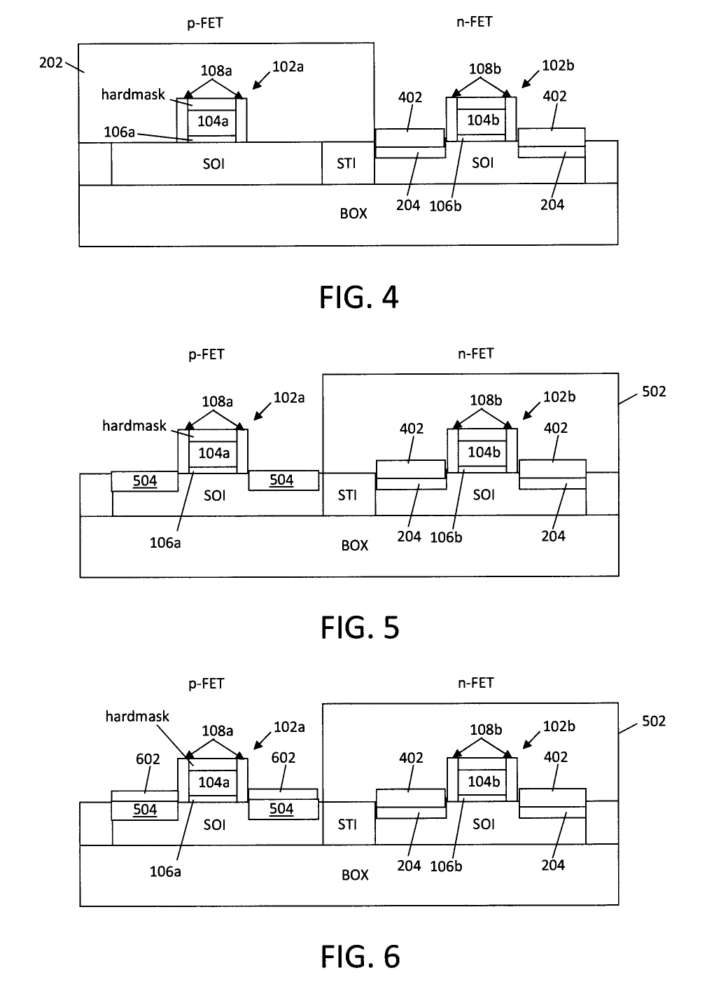

As shown in FIG. 4, the same mask (i.e., hardmask 202) used during the n-FET source and drain doping is now used to block the p-FET devices during silicidation of the n-FET source and drain regions, so as to form contacts to the n-FET source and drain regions. To begin the silicidation process, a contact metal(s) is first deposited onto the wafer (e.g., using evaporation or sputtering). Silicide will form only where the metal and the source/drain semiconductor are in contact. Thus the process is self-aligning (a self-aligned silicide is also referred to herein as a salicide). As provided above, in order to integrate the present dual silicide steps along with the source/drain doping in the fabrication process—i.e., to enable using the same mask for doping and silicidation in the respective devices, it is preferable that refractory metals are employed as the contact metals. Refractory metals have a melting point that is greater than about 1,200° C. Thus, refractory metals will be able to withstand the temperatures associated with the source/drain doping. Accordingly, based on the present process flow, the contact metal in the source/drain silicide formed in the n-FET device(s) would be able to withstand the high temperatures associated with the subsequent doping of the p-FET device(s)—see below. By comparison, conventional contact metals, such as nickel based silicides, would agglomerate subject to these elevated temperatures. Accordingly, with conventional process flows, the silicidation must be performed later in the process, thus warranting multiple masking steps thereby increasing production time, complexity and costs.

Suitable refractory metals include, but are not limited to, titanium (Ti), zirconium (Zr), hafnium (Hf), vanadium (V), niobium (Nb), tantalum (Ta), chromium (Cr), molybdenum (Mo), tungsten (W), and combinations including at least one of the foregoing metals. The silicide may also include one or more alloying elements, such as aluminum (Al).

After metal deposition, an anneal is performed to intersperse the metal within the source and drain regions of the n-FET devices to form a silicide 402. Unreacted metal is then selectively etched away by wet etch. See FIG. 4. As provided above, the source/drain regions of the devices may include materials such as Si, Ge, and SiGe. However, to adhere to conventional terminology, the resulting product is referred to generically herein as a “silicide” which is meant to encompass Si-based silicides, Ge-based germanides, and SiGe-based germanosilicides. According to an exemplary embodiment, the anneal is performed at a temperature of from about 300° C. to about 1,200° C. for a duration of from about 1 second to about 1 hour.

Following the silicidation of the n-FET device(s), the hardmask is removed from the p-FET devices (using, for example, a wet etch) and the process is then repeated for doping and silicidation of the p-FET devices. Namely, as shown in FIG. 5 a hardmask 502 is formed covering/masking the n-FET device(s). By way of example only, the hardmask 502 can be formed from silicon oxide or silicon nitride. In the case where the present dual silicide process is being performed for multiple p-FET and n-FET devices on a common wafer, all of the n-FET devices on the wafer will at this stage be masked off relative to all of the p-FET devices. The hardmask 502 may be selectively formed over/blocking the n-FET devices in the same manner as hardmask 202, see above.

Next, source and drain regions 504 are formed in the p-FET devices. As described above, doping of the source and drain regions may be performed in-situ or ex-situ. For example, the dopants may be introduced during growth of an epitaxial material (e.g., epitaxial Si, Ge, SiGe, etc.) in the source drain regions of the p-FET devices, resulting in in-situ doped epitaxial source/drain regions. An activation anneal may then be performed to activate the dopants. Alternatively, ex-situ doping can involve implanting a dopant or dopants and then activating the dopants by way of an activation anneal. As provided above, P, As, and Sb are suitable n-type dopants and B, Al, In, and Ga are suitable p-type dopants. Dopant concentrations of the from about 1×10¹⁹ atoms/cm³ to about 1×10²² atoms/cm³ may be employed. The activation anneal of the wafer may be performed at a temperature of from about 800° C. to about 1,500° C. Advantageously, as provided above, according to the present techniques refractory contact metals are preferably employed during the source/drain silicidation. Refractory metals can withstand temperatures up to about 1,200° C. Thus, the activation anneal now being performed to activate the dopants will not affect the silicide contacts already formed in the n-FET devices. By comparison, with conventional silicide processes and materials, the high temperature annealing would have to be completed prior to deposition of the contact metal. Thus, to implement a dual silicide process in a conventional scheme involves multiple masking layers which introduces increased complexity and cost to the manufacturing process. Also, as provided above, the present techniques may be implemented in accordance with a replacement gate scheme, wherein the replacement gate is placed later in the process, i.e., following both the source/drain doping and silicidation. The replacement gate formation often requires high temperature anneals to set the gate workfunction which, without the use of refractory contact metals, would damage the source/drain contacts if they were formed prior to the replacement gate. Thus, implementing a dual silicide scheme in a replacement gate flow with conventional techniques and materials would drastically increase production complexity and costs, perhaps even prohibitively so.

As shown in FIG. 6, an optional surface treatment 602 of the n-FET device source and drain regions may be performed, if so desired, using shallow surface implantation or ALD of dopants. Such a surface treatment can be used to reduce the metal/semiconductor interface resistance. According to an exemplary embodiment, the dopant(s) are applied at a concentration of from about 1×10¹⁹/cm³ to pure atomic layers of dopants. As provided above, P, As, and Sb are suitable n-type dopants and B, Al, In, and Ga are suitable p-type dopants.

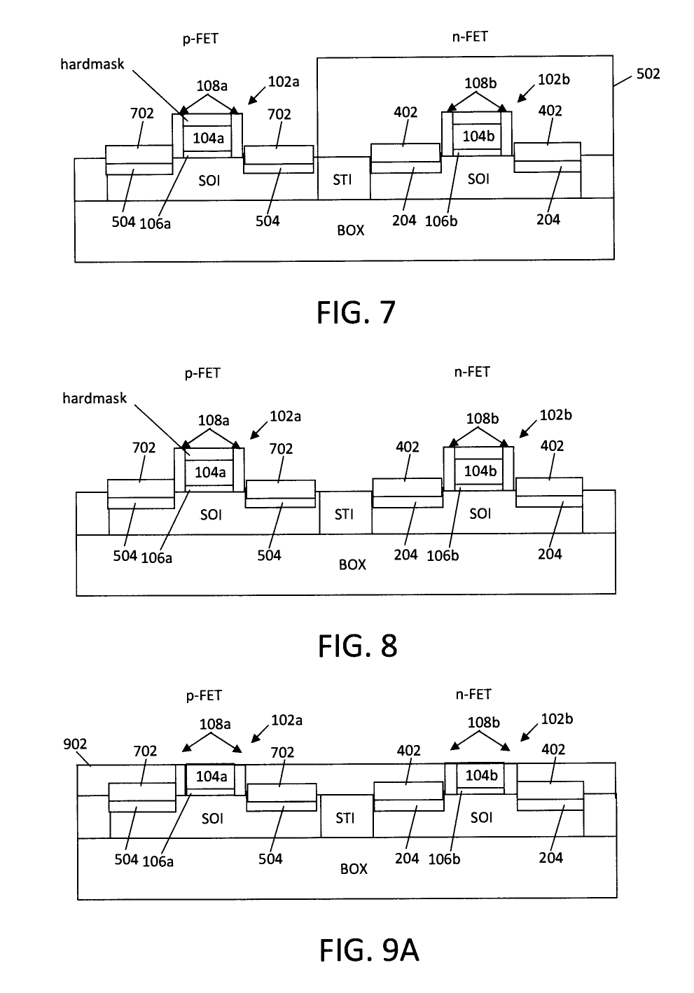

As shown in FIG. 7, the same mask (i.e., hardmask 502) used during the p-FET source and drain doping is now used to block the n-FET devices during silicidation of the p-FET source and drain regions, so as to form contacts to the p-FET source and drain regions. To begin the silicidation process, a contact metal(s) is first deposited onto the wafer (e.g., using evaporation or sputtering). The same, or different, contact metal(s) may be employed in the p-FET as were employed in the n-FET, see above. Advantageously, with the present dual silicide process, the metal or metals employed can be tailored to the particular devices being fabricated, thereby addressing the contact resistance issues described above. For instance, one particular contact metal (or combination of metals) with matched work function to the device can be used in conjunction with the p-FET devices and another, different contact metal (or combination of contact metal) with matched work function to the device can be used in conjunction with the n-FET devices.

As provided herein, an alloying metal can be used in conjunction with the refractory metal to form the silicide. According to an exemplary embodiment, the alloying metal is varied to configure the workfunction to the particular device. Thus, in this example, the same (or different) refractory metal is used in both the p-FET and n-FET devices in combination with a different alloying metal. As provided above, a suitable alloying metal for the n-FET devices is aluminum. Suitable alloying metals for the p-FET devices include, but are not limited to, platinum (Pt), rhenium (Re), rhodium (Rh), and/or combinations including at least one of the foregoing metals. To use a simple example, the same refractory element is used as the contact metal in both the p-FET and the n-FET devices, however Al is included as an alloying metal in the n-FET devices and one or more of Pt, Re, and Rh is included as an alloying metal in the p-FET devices. Of course, use of an alloying metal is optional and the particular refractory metal(s) used may be varied depending on the device type.

As provided above, silicide will form only where the metal and the source/drain semiconductor are in contact. Thus the process is self-aligning (a salicide).

As provided above, in order to integrate the present dual silicide steps along with the source/drain doping in the fabrication process—i.e., to enable using the same mask for doping and silicidation in the respective devices, it is preferable that refractory metals are employed as the contact metals. Refractory metals have a melting point that is greater than about 1,200° C. and thus will be able to withstand the temperatures associated with the source/drain doping. As provided above, the exact order of fabrication, i.e., n-FET devices then p-FET, or vice-a-versa is not important, and thus the p-FET source/drain doping and silicidation may be performed before that of the n-FET devices. Thus, employing refractory contact metals in the p-FET devices insures that any subsequent high temperature annealing conditions will not damage the contacts. Further, as detailed above, the use of a replacement gate scheme introduces high temperatures near the end of the process. Advantageously, the use of the refractory metals in the present scheme permits the integration of a replacement gate scenario.

Suitable refractory metals include, but are not limited to, Ti, Zr, Hf, V, Nb, Ta, Cr, Mo, W, and combinations including at least one of the foregoing metals. The silicide may also include one or more alloying elements, such as platinum (Pt), rhenium (Re), rhodium (Rh), and combinations including at least one of the foregoing metals. It is notable that the

After metal deposition, an anneal is performed to intersperse the metal within the source and drain regions of the n-FET devices to form a silicide 702. Unreacted metal is selectively etched away by wet etch. See FIG. 7. According to an exemplary embodiment, the anneal is performed at a temperature of from about 300° C. to about 1,200° C. for a duration of from about 1 second to about 1 hour.

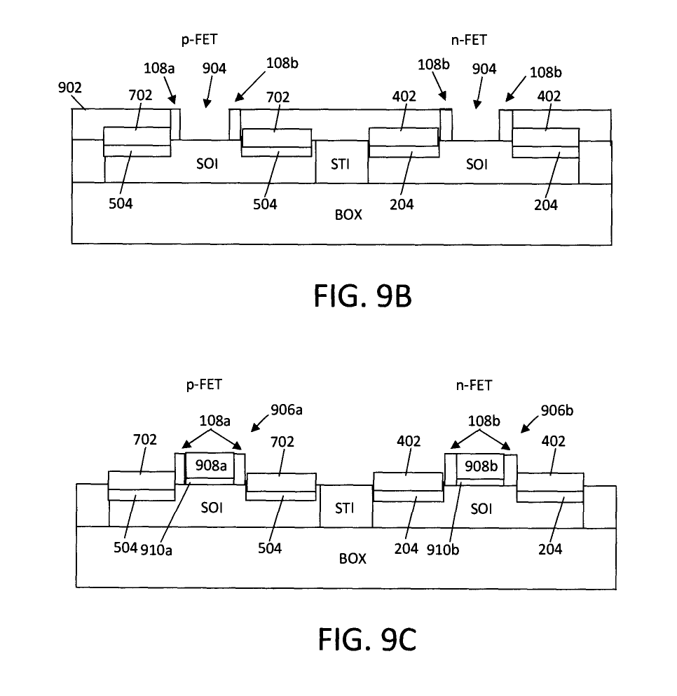

As shown in FIG. 8, the hardmask is removed from the n-FET devices (using, for example, a wet etch). Any further processing of the devices may now be performed. By way of example only, as highlighted above, the present techniques may be easily and effectively integrated with a gate last process flow, and as detailed above the gates present up to this point in the process are called “dummy gates”—e.g., poly-silicon gates that serve as a placeholder and will be removed and replaced with a “replacement” gate. An exemplary dummy gate/replacement gate process is now described by way of reference to FIGS. 9A-C.

Beginning with the structure shown in FIG. 8, in order to permit effective removal and replacement of the dummy gates, a filler layer 902 is deposited onto the wafer and planarized, using for example, chemical-mechanical polishing (CMP). See FIG. 9A. Suitable filler materials include, but are not limited to, a dielectric material. CMP will serve to remove the hardmasks from over the dummy gates (compare, for example, FIG. 8 and FIG. 9A).

Next, as shown in FIG. 9B, the dummy gates and the dummy gate oxide (104 and 106, respectively, see above) are removed selective to the filler layer 902. According to an exemplary embodiment, the dummy gates are removed using a chemical etching process, such as chemical down stream or potassium hydroxide (KOH) etching, or reactive ion etching (RIE). The dummy gate dielectric is removed after removal of the dummy gates using, for example, wet etches like dilute hydrofluoric (HF) acid or buffered oxide etch (BOE)—when the dummy gate dielectric is an oxide. As shown in FIG. 9B, removal of the dummy gates forms trenches 904 in the filler layer.

As shown in FIG. 9C, the trenches 904 in the filler layer are then filled with a replacement gate stack material(s) to form replacement gate stacks 906a, 906b, etc. Each replacement gate stack includes a gate electrode 908a, 908b, etc. over a gate dielectric 910a, 910b, etc. By way of example only, the gate electrode may be formed from a metal(s) and/or doped polysilicon. The gate dielectric may be formed from an oxide, such as silicon oxide, or hafnium oxide. High-k dielectrics, such as hafnium oxide, are preferable when a metal gate electrode is employed. It is notable that the configuration of the gate electrode depicted in the figures is merely exemplary. By way of example only, gate stack configurations without a gate dielectric are possible.

The filler layer 902 may now be removed and a high temperature anneal (e.g., at temperatures of from about 700° C. to about 1,500° C.) is then employed to set the workfunction of the replacement gate. With conventional silicidation techniques and materials, this gate anneal would be damaging to the contact metals. Accordingly, with conventional processes, silicidation is held off until after the replacement gate is formed. However, to implement a dual silicide scenario with a replacement gate flow would introduce a great amount of complexity to the manufacturing process. Advantageously, as described in detail above, the present techniques permit use of a single mask for doping and silicidation of each device type, all prior to the formation of the replacement gate, greatly reducing the manufacturing complexity, number of steps, costs, etc.

It is notable that the use of a gate last approach is only one possible exemplary implementation of the present techniques. The depiction of a gate last process is provided merely to illustrate its compatibility with the present techniques. The present techniques could however be implemented in the same manner as described above in a gate first (or any other) device fabrication scenario.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A method for silicidation, comprising the steps of:
(a) providing a wafer having at least one first active area and at least one second active area defined therein;
(b) masking the first active area with a first hardmask;
(c) doping the second active area;
(d) forming a silicide in the second active area comprising at least one metal having a melting point that is greater than about 1,200° C., wherein the first hardmask serves to mask the first active area during both the doping step (c) and the forming step (d);
(e) removing the first hardmask;
(f) masking the second active area with a second hardmask;
(g) doping the first active area;
(h) forming a silicide in the first active area comprising at least one metal having a melting point that is greater than about 1,200° C., wherein the second hardmask serves to mask the second active area during both the doping step (g) and the forming step (h); and
(i) removing the second hardmask.

2. The method of claim 1, wherein the wafer comprises a semiconductor-on-insulator (SOI) wafer or a bulk semiconductor wafer.

3. The method of claim 1, further comprising the step of:
forming (i) at least one p-channel field effect transistor (p-FET) device in the first active area of the wafer and (ii) at least one n-channel FET (n-FET) device in the second active area of the wafer.

4. The method of claim 3, further comprising the step of:
forming at least one first gate stack on the wafer over the first active area; and
forming at least one second gate stack on the wafer over the second active area.

5. The method of claim 4, wherein the first gate stack and the second gate stack both comprise dummy gates.

6. The method of claim 5, further comprising the steps of:
removing the dummy gates after steps (a)-(i) have been performed; and
replacing the dummy gates with replacement gates.

7. The method of claim 3, wherein the doping step (c) is performed to form source and drain regions for the n-FET device, and wherein the forming step (d) is performed to form source and drain contacts for the n-FET device.

8. The method of claim 3, wherein the doping step (g) is performed to form source and drain regions for the p-FET device, and wherein the forming step (h) is performed to form source and drain contacts for the p-FET device.

9. The method of claim 1, wherein one or more of the doping step (c) and the doping step (g) are performed in-situ, the method further comprising the steps of:
growing an epitaxial material in one or more of the first active area and the second active area;
introducing at least one dopant during growth of the epitaxial material; and
annealing the wafer at a temperature of from about 800° C. to about 1,500° C. to activate the dopants.

10. The method of claim 1, wherein one or more of the doping step (c) and the doping step (g) are performed ex-situ, the method further comprising the steps of:
implanting at least one dopant into one or more of the first active area and the second active area; and
annealing the wafer at a temperature of from about 800° C. to about 1,500° C. to activate the dopants.

11. The method of claim 1, wherein the silicide in the first active area comprises at least one refractory metal selected from the group consisting of: titanium, zirconium, hafnium, vanadium, niobium, tantalum, chromium, molybdenum, tungsten, and combinations comprising at least one of the foregoing metals.

12. The method of claim 1, wherein the silicide in the second active area comprises at least one refractory metal selected from the group consisting of titanium, zirconium, hafnium, vanadium, niobium, tantalum, chromium, molybdenum, tungsten, and combinations comprising at least one of the foregoing metals.

13. The method of claim 3, wherein the silicide in the first active area further comprises at least one alloying metal selected from the group consisting of: platinum, rhenium, rhodium and combinations comprising at least one of the foregoing metals.

14. The method of claim 3, wherein the silicide in the second active area further comprises aluminum as an alloying metal.

15. An electronic device, comprising:
a wafer having at least one first active area and at least one second active area defined therein;
at least one p-FET device formed in the first active area of the wafer, the p-FET device comprising doped p-FET source and drain regions, and silicide contacts to the p-FET source and drain regions, wherein the silicide contacts to the p-FET source and drain regions comprise at least one metal having a melting point that is greater than about 1,200° C.; and
at least one n-FET device formed in the second active area of the wafer, the n-FET device comprising doped n-FET source and drain regions and silicide contacts to the n-FET source and drain regions, wherein the silicide contacts to the n-FET source and drain regions comprise at least one metal having a melting point that is greater than about 1,200° C.

16. The device of claim 15, wherein the wafer comprises a semiconductor-on-insulator (SOI) wafer or a bulk semiconductor wafer.

17. The device of claim 15, further comprising:
at least one p-FET gate stack on the wafer over the first active area; and
at least one n-FET gate stack on the wafer over the second active area.

18. The device of claim 17, wherein the p-FET gate stack and the n-FET gate stack both comprise dummy gates.

19. The device of claim 15, wherein the silicide contacts to the p-FET source and drain regions comprise at least one refractory metal selected from the group consisting of: titanium, zirconium, hafnium, vanadium, niobium, tantalum, chromium, molybdenum, tungsten, and combinations comprising at least one of the foregoing metals.

20. The device of claim 15, wherein the silicide contacts to the n-FET source and drain regions comprise at least one refractory metal selected from the group consisting of: titanium, zirconium, hafnium, vanadium, niobium, tantalum, chromium, molybdenum, tungsten, and combinations comprising at least one of the foregoing metals.

21. The device of claim 15, wherein the silicide contacts to the p-FET source and drain regions further comprise at least one alloying metal selected from the group consisting of: platinum, rhenium, rhodium and combinations comprising at least one of the foregoing metals.

22. The device of claim 15, wherein the silicide contacts to the n-FET source and drain regions further comprise aluminum as an alloying metal.
